(19) United States
(12) Patent Application Publication
(10) Pub. No.: US 2026/0206547 A1
(43) Pub. Date: Jul. 16, 2026

(54) SEMICONDUCTOR APPARATUS AND METHOD FOR MANUFACTURING SEMICONDUCTOR APPARATUS

(71) Applicant: SONY SEMICONDUCTOR SOLUTIONS CORPORATION, KANAGAWA (JP)

(72) Inventor: Yasunori SOGOH, KANAGAWA (JP)

(21) Appl. No.: 19/135,060

(22) PCT Filed: Nov. 28, 2023
(86) PCT No.: PCT/JP2023/042468

§ 371 Date: Jun. 2, 2025

(30) Foreign Application Priority Data
Dec. 7, 2022 (JP) 2022-195410

(51) Int. Cl. H10P 74/00; H10F 39/00; H10P 74/20

(52) U.S. Cl. CPC H10P 74/273; H10F 39/811; H10P 74/207

(57) ABSTRACT

The present technology relates to a semiconductor apparatus and a method for manufacturing a semiconductor apparatus that make it possible to provide a semiconductor apparatus that prevents, when semiconductor apparatuses are stacked on each other, reduction in the adhesion strength between the stacked semiconductor apparatuses.

The semiconductor apparatus includes a first electrode covered with a first insulating film, and a second electrode covered with the first insulating film and a second insulating film of a material different from that of the first insulating film. At least one surface of side surfaces of the second electrode is covered with the second insulating film, and a remaining surface is covered with the first insulating film. The present technology can be applied to a semiconductor apparatus that is subjected to an inspection to determine whether it is non-defective before it is stacked on other semiconductor apparatuses, in a case in which multiple semiconductor apparatuses are stacked on each other, for example.

### TECHNICAL FIELD

The present technology relates to a semiconductor apparatus and a method for manufacturing a semiconductor apparatus and, for example, relates to a semiconductor apparatus and a method for manufacturing a semiconductor apparatus which are suitable for application to chips to be stacked.

### BACKGROUND ART

For example, there has been proposed a technique of adopting, in an imaging apparatus that includes an imaging element such as a CMOS (Complementary Metal Oxide Semiconductor) image sensor and a CCD (Charge Coupled Device), a stacked structure in which a chip having the imaging element formed therein and a logic circuit which processes a signal transmitted from the imaging element are stacked on each other (for example, see PTL 1).

### CITATION LIST

### Patent Literature

### PTL 1

PCT Patent Publication No. WO2015/159766

### SUMMARY

### Technical Problem

There has been proposed that, in a case where a stacked structure in which multiple chips are stacked is adopted, at a stage before stacking the chips, a determination whether the chips are non-defective or defective is made, and chips having been determined to be non-defective are used to be stacked. When it is determined whether chips are non-defective, a needle for inspection is pushed onto a pad for inspection, and there is a possibility that the pushed needle causes irregularities on an electrode of the pad.

In a case where a chip with irregularities is processed and stacked on another chip, there is a possibility that the connection strength between the chips is reduced.

The present technology has been made in view of such circumstances, and makes it possible to prevent the connection strength from being reduced.

### Solution to Problem

A semiconductor apparatus according to one aspect of the present technology includes a first electrode covered with a first insulating film, and a second electrode covered with the first insulating film and a second insulating film of a material different from that of the first insulating film.

A method for manufacturing a semiconductor apparatus according to another aspect of the present technology includes removing a conductive material located in an opening of a pad onto which a needle for inspection has been pushed when an inspection to determine whether the semiconductor apparatus is non-defective has been performed, forming a second insulating film of a material different from that of a first insulating film formed on the conductive material of the pad, on a region including a region from which the conductive material has been removed, and planarizing the second insulating film thus formed.

In the semiconductor apparatus according to the one aspect of the present technology, the first electrode covered with the first insulating film and the second electrode covered with the first insulating film and the second insulating film of a material different from that of the first insulating film are provided.

In the method for manufacturing the semiconductor apparatus according to the other aspect of the present technology, a conductive material located in an opening of a pad onto which a needle for inspection has been pushed when an inspection to determine whether the semiconductor apparatus is non-defective has been performed is removed, a second insulating film of a material different from that of a first insulating film formed on the conductive material of the pad is formed on a region including a region from which the conductive material has been removed, and the second insulating film thus formed is planarized.

Note that the semiconductor apparatus may be an independent apparatus or may be an internal block included in an apparatus.

### BRIEF DESCRIPTION OF DRAWINGS

FIG. 1 is a view illustrating a configuration of an embodiment of a semiconductor apparatus to which the present technology is applied.

FIG. 2 is a view illustrating the semiconductor apparatus in an inspection.

FIG. 3 depicts views each illustrating a protrusion generated after the inspection.

FIG. 4 depicts views illustrating a manufacturing process of the semiconductor apparatus according to a first embodiment.

FIG. 5 is a view illustrating a configuration example of the semiconductor apparatus according to the first embodiment.

FIG. 6 is a view illustrating a configuration example of a semiconductor apparatus according to a second embodiment.

FIG. 7 depicts views illustrating a manufacturing process of the semiconductor apparatus according to the second embodiment.

FIG. 8 is a view illustrating a configuration example of a semiconductor apparatus according to a third embodiment.

FIG. 9 depicts views illustrating a manufacturing process of the semiconductor apparatus according to the third embodiment.

FIG. 10 is a view illustrating a configuration example of a semiconductor apparatus according to a fourth embodiment.

FIG. 11 is a view illustrating a manufacturing process of the semiconductor apparatus according to the fourth embodiment.

FIG. 12 is a view illustrating a configuration example of a semiconductor apparatus according to a fifth embodiment.

FIG. 13 is a view illustrating a configuration example of a semiconductor apparatus according to a sixth embodiment.

FIG. 14 is a view illustrating a configuration example of a semiconductor apparatus according to a seventh embodiment.

FIG. 15 is a diagram illustrating a configuration example of electronic equipment.

### DESCRIPTION OF EMBODIMENTS

Modes for carrying out the present technology (hereinafter referred to as embodiments) will hereinafter be described.

### Configuration of Semiconductor Apparatus According to First Embodiment

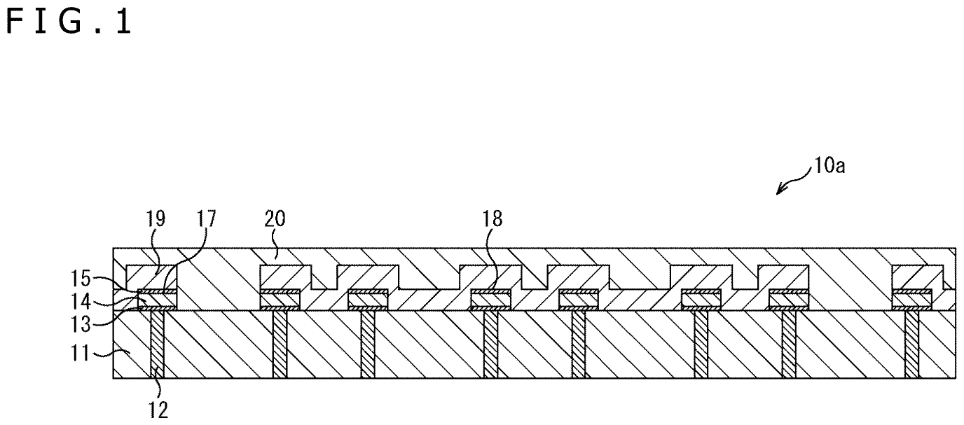

FIG. 1 is a view illustrating a configuration of a semiconductor apparatus according to an embodiment to which the present technology is applied. A semiconductor apparatus 10a illustrated in FIG. 1 can be applied to an imaging element such as a CMOS (Complementary Metal Oxide Semiconductor) image sensor and a CCD (Charge Coupled Device), a memory that stores a signal from the imaging element, a processing circuit that processes a signal from the imaging element, an AI (Artificial Intelligence) circuit that performs AI processing, and the like.

FIG. 1 illustrates a part related to electrodes and wiring of the semiconductor apparatus 10a, and description thereof is given. The semiconductor apparatus 10a has an electrode 12 formed in a semiconductor substrate 11. On a surface on the upper side of the semiconductor substrate 11 in FIG. 1, a pad electrode 17 and a wiring electrode 18 are provided.

The pad electrode 17 and the wiring electrode 18 basically have a similar configuration except for a part to be described later. The pad electrode 17 and the wiring electrode 18 each have a barrier metal 13, an aluminum film 14, and a titanium film 15 stacked on one another.

For example, tantalum (Ta), titanium (Ti), tungsten (W), zirconium (Zr), a nitride film of these elements, a carbonized film of these elements, and the like can be used for the barrier metal 13. In place of the aluminum film 14, such a metal (conductor) as cobalt (Co), nickel (Ni), palladium (Pd), platinum (Pt), or gold (Au) can be used.

An upper surface and one surface of the left and right side surfaces of the pad electrode 17 in FIG. 1 are covered with a first insulating film 19, and the other surface of the left and right side surfaces of the pad electrode 17 is covered with a second insulating film 20. The wiring electrode 18 is covered with the first insulating film 19, and the first insulating film 19 is covered with the second insulating film 20.

The first insulating film 19 is assumed to be an insulating film having high embeddability, and an inorganic or organic oxide film such as HDP (High Density Plasma) and SOG (Spin On Glass) can be used for the first insulating film 19, for example. p TEOS (Plasma Tetra Ethyl Oxysilane) can be used for the second insulating film 20, for example.

### <Step Generated in Pad Portion in Manufacturing>

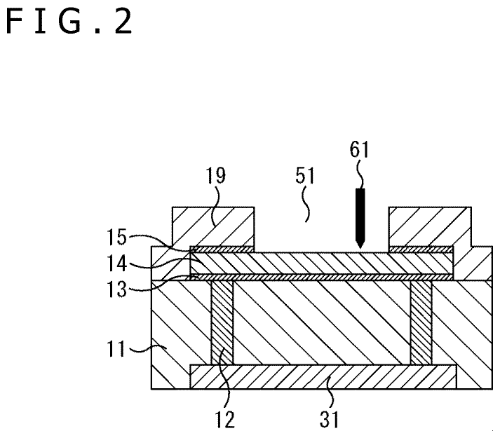

FIG. 2 illustrates an enlarged view of the pad electrode 17 in the manufacturing. As illustrated in FIG. 2, the pad electrode 17 is connected to the electrode 12 provided in the semiconductor substrate 11, and the electrode 12 is connected to a wire 31 provided in the semiconductor substrate 11. The pad electrode 17 forms a pad portion 51 onto which a needle 61 for inspection is pushed in the manufacturing.

An opening of the pad portion 51 used as a pad for inspection is in a state in which the aluminum film 14 is exposed, that is, in a state in which the first insulating film 19 on the aluminum film 14 has been removed. Note that the second insulating film 20 is not deposited at the time of an inspection.

The pad portion 51 includes the opening at which the aluminum film 14 is exposed and the pad electrode 17 on which the first insulating film 19 is stacked and connected to the aluminum film 14 in the opening. In the following description, in a case in which the pad portion 51 is stated, there are a case in which the pad portion 51 includes the pad electrode 17 and a case in which the pad portion 51 includes only the opening.

When the needle 61 for inspection is pushed onto the exposed aluminum film 14 to perform an inspection, it is determined whether the semiconductor apparatus 10a is non-defective or not, and only the semiconductor apparatus 10a that has been determined to be non-defective is to be stacked on another semiconductor apparatus. When the second insulating film 20 is deposited on the pad portion 51 after the inspection, a film formation of the pad portion 51 with the second insulating film 20 is achieved.

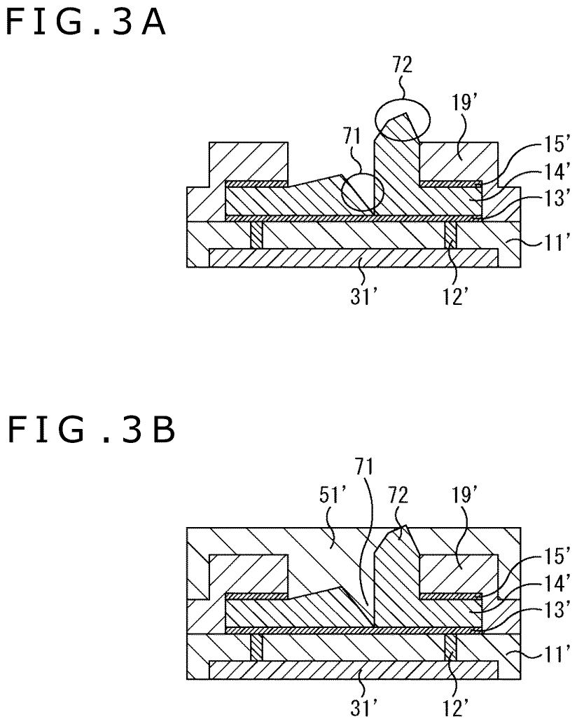

With reference to FIG. 3, irregularities generated in the pad portion 51 at the time of the inspection are described. When the needle 61 for inspection is pushed onto the aluminum film 14 in the inspection, there is a possibility that a mark 71 of the needle 61 is left on an aluminum film 14′ (description is made with a prime added to the aluminum film 14 in order to distinguish the aluminum film 14′ from the aluminum film 14 of the semiconductor apparatus 10a to which the present technology is applied) as illustrated in A of FIG. 3. If the mark 71 is left, there is a possibility that a protrusion 72 in which the aluminum film 14′ has a protruding shape is formed as illustrated in A of FIG. 3, for example.

Although A of FIG. 3 illustrates a case where the protrusion 72 is formed on the right side in the figure, there are various cases such as a case where the protrusion 72 is formed on the left side and a case where the protrusion 72 is formed on each of the left and right sides. When the second insulating film 20 is formed in the case where the protrusion 72 is formed as described above, a state illustrated in B of FIG. 3 is provided. The second insulating film 20 is formed on the aluminum film 14′ in the pad portion 51. Since the aluminum film 14′ has the mark 71 of the needle 61 and the protrusion 72, the second insulating film 20 is not uniformly formed.

For example, in a case where the protrusion 72 has such a shape that protrudes from the second insulating film 20, there is a possibility that connection failure occurs when a semiconductor apparatus 10a′ and another semiconductor apparatus are stacked on each other. Due to irregularities generated in the pad portion 51, when the second insulating film 20 is formed thereon, a space is generated in the second insulating film 20 formed on the pad portion 51, resulting in reduction of the adhesion strength, and occurrence of peeling-off may be caused.

### Manufacturing Process According to First Embodiment

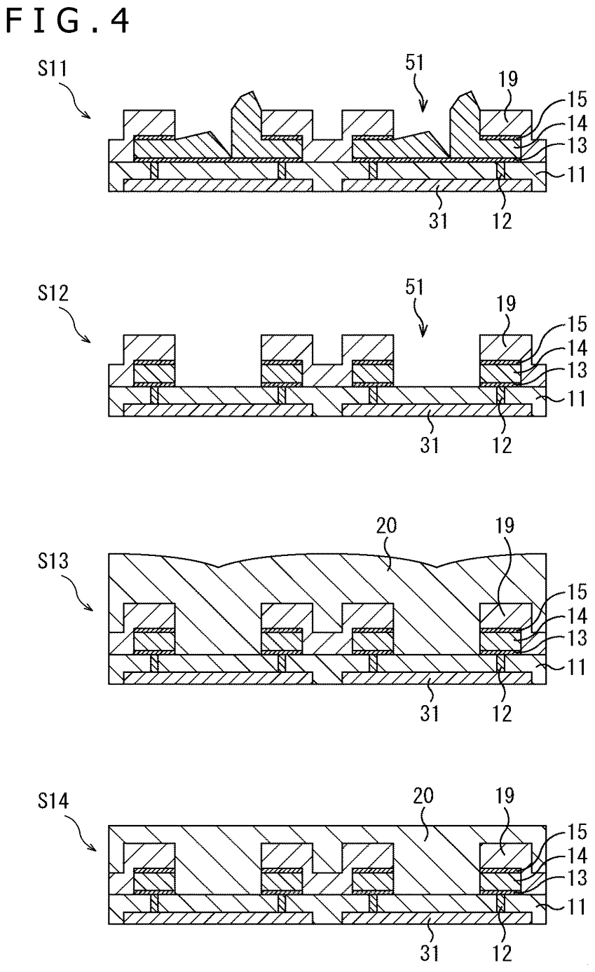

With reference to FIG. 4, a manufacturing process for preventing the adhesion strength from being reduced due to irregularities generated on the aluminum film 14 in the manufacturing as described with reference to FIG. 3 is described.

FIG. 4 depicts views illustrating a manufacturing process of the semiconductor apparatus 10a according to the first embodiment. Step S11 illustrates the pad portion 51 of the semiconductor apparatus 10a obtained after the needle 61 for inspection is pushed and the inspection is performed, and corresponds to the semiconductor apparatus 10a in the state illustrated in A of FIG. 3. The first insulating film 19 is in a state in which a part other than a necessary part thereof has been removed after its formation.

As described above, an HDP (High Density Plasma) film deposited by HDP CVD with high embeddability can be applied as the first insulating film 19. The HDP film is formed by a chemical vapor deposition process using high density plasma or by an apparatus implementing the chemical vapor deposition process. Using high density plasma results in high decomposition efficiency of the source gas and a high film deposition rate. At the same time, the ion density in plasma is also high, so that the process further proceeds to apply a bias to a substrate wafer, and these ions are actively taken in the substrate wafer, thereby allowing for sputtering of a protruding portion or a corner portion of the deposited film and also providing a self-planarizing function. Hence, in formation of an insulating film between layers in fine multilayer wiring, inter-wire embeddability and flatness can be enhanced.

In step S12, the aluminum film 14 and the barrier metal 13 in a region of the pad portion 51 are removed by etching. Etching in a pattern of the opening of the pad portion 51 makes it possible to increase an aperture ratio and decrease differences between a rough pattern and a dense pattern compared to the conventional technology.

In step S13, the second insulating film 20 is formed. For example, p TEOS is used as the second insulating film 20 and deposited. In step S14, the second insulating film 20 is planarized by CMP (Chemical Mechanical Polishing), for example. A global step is subjected to CMP, so that planarization in which variation in thicknesses of films in a wafer surface is small can be achieved.

As described above, irregularities on the aluminum film 14, such as the mark 71 of the needle 61 and the protrusion 72 generated by pushing of the needle 61, are removed by etching and planarized, and the second insulating film 20 is then formed, thereby making it possible to prevent a space from being generated in the second insulating film 20 and prevent occurrence of peeling-off when another semiconductor apparatus is stacked thereon.

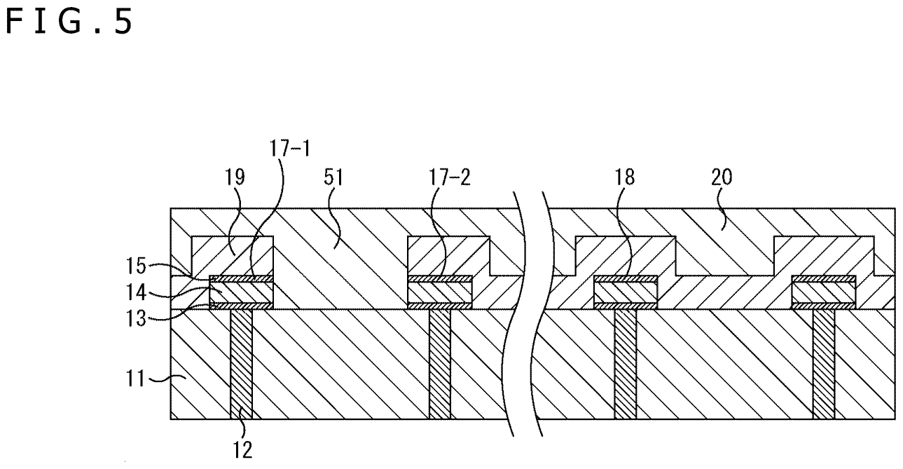

By the manufacturing process described above, the semiconductor apparatus 10a illustrated in FIG. 1 is manufactured. With reference to FIG. 5, the pad electrode 17 and the wiring electrode 18 are described again.

FIG. 5 is an enlarged view of a part corresponding to the pad portion 51 and a part in which the wiring electrode 18 is disposed, in the semiconductor apparatus 10a illustrated in FIG. 1. The opening of the pad portion 51 is in a state in which only the second insulating film 20 is formed, as the aluminum film 14 and the barrier metal 13 have been removed by etching in step S12 (FIG. 4).

The aluminum film 14 in the pad portion 51 is in a form of a single continuous film before the etching is performed. However, after the etching, the aluminum film 14 is in a state of being divided into one part formed in a pad electrode 17-1 and another part formed in a pad electrode 17-2. A surface on the upper side and a surface on the left side of the pad electrode 17-1 in FIG. 5 are covered with the first insulating film 19, but a surface on the right side of the pad electrode 17-1 in FIG. 5 is covered not with the first insulating film 19 but with the second insulating film 20. Similarly, a surface on the upper side and a surface on the right side of the pad electrode 17-2 in FIG. 5 are covered with the first insulating film 19, but a surface on the left side of the pad electrode 17-2 in FIG. 5 is covered not with the first insulating film 19 but with the second insulating film 20.

Meanwhile, a surface on the upper side, a surface on the left side, and a surface on the right side of the wiring electrode 18 in FIG. 5 are covered with the first insulating film 19.

A lower surface of the pad electrode 17 and a lower surface of the wiring electrode 18 are both in contact with the semiconductor substrate 11.

The surfaces of the pad electrode 17 and the wiring electrode 18 which are in contact with the semiconductor substrate 11 are referred to as the lower surfaces, and focus is placed on upper surfaces, left surfaces, and right surfaces other than the lower surfaces. One surface of the upper surface, the left surface, and the right surface of the pad electrode 17 is covered with an insulating film of a material different from that of the other two surfaces. The upper surface, the left surface, and the right surface of the wiring electrode 18 are all covered with an insulating film of the same material. In such a manner, the pad electrode 17 is covered with insulating films of different materials, but the wiring electrode 18 is covered with an insulating film of the same material.

While the side surfaces of the pad electrode 17 are covered with different insulating films, the side surfaces of the wiring electrode 18 are covered with the same insulating film.

At least one electrode of the electrodes formed in the semiconductor apparatus 10a is configured to be covered with two or more different insulating films.

Note that there has been described as an example, here, a case where, with a substantially central portion of the pad portion 51 as the opening, the material forming the electrode, such as the aluminum film 14, in the opening is removed, causing the pad electrode 17-1 and the pad electrode 17-2 to remain. There may be adopted a configuration in which an opening is provided on the left side or the right side of the pad portion 51, and the material forming the electrode, such as the aluminum film 14, in the opening is removed, causing either the pad electrode 17-1 or the pad electrode 17-2 to remain.

### Configuration of Semiconductor Apparatus According to Second Embodiment

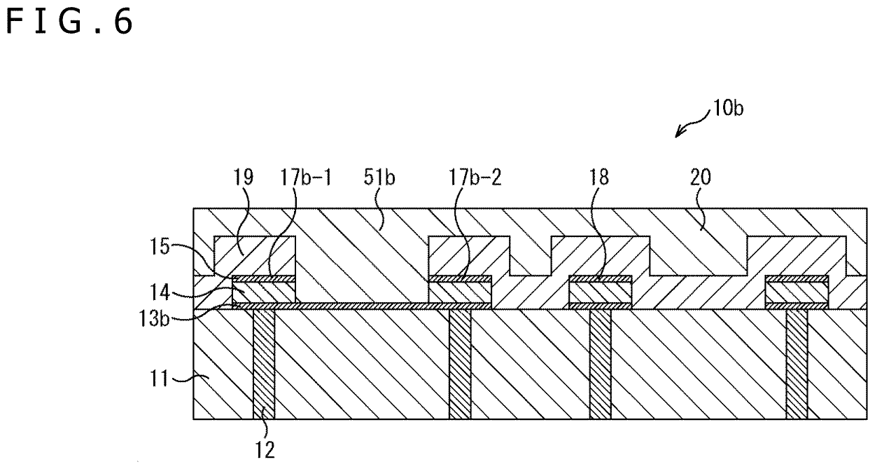

FIG. 6 is a view illustrating a configuration example of a semiconductor apparatus 10b according to the second embodiment. While only a region of the semiconductor apparatus 10b in which a pad electrode 17b and the wiring electrode 18 are located is illustrated in FIG. 6, a basic configuration of the semiconductor apparatus 10b is similar to that of the semiconductor apparatus 10a illustrated in FIG. 1 and FIG. 6. In the following description, parts which are the same as those of the semiconductor apparatus 10a according to the first embodiment are denoted by the same reference signs, and description thereof is omitted as appropriate.

The semiconductor apparatus 10b according to the second embodiment illustrated in FIG. 6 is different from the semiconductor apparatus 10a according to the first embodiment illustrated in FIG. 6 in that a barrier metal 13b is formed in an opening of a pad portion 51b, but is similar to the semiconductor apparatus 10a in other respects.

The barrier metal 13b in the pad portion 51b of the semiconductor apparatus 10b is formed in a state of being continuous over an area ranging from a pad electrode 17b-1 to a pad electrode 17b-2. In such a manner, the barrier metal 13b may remain in the opening of the pad portion 51b.

### Manufacturing Process According to Second Embodiment

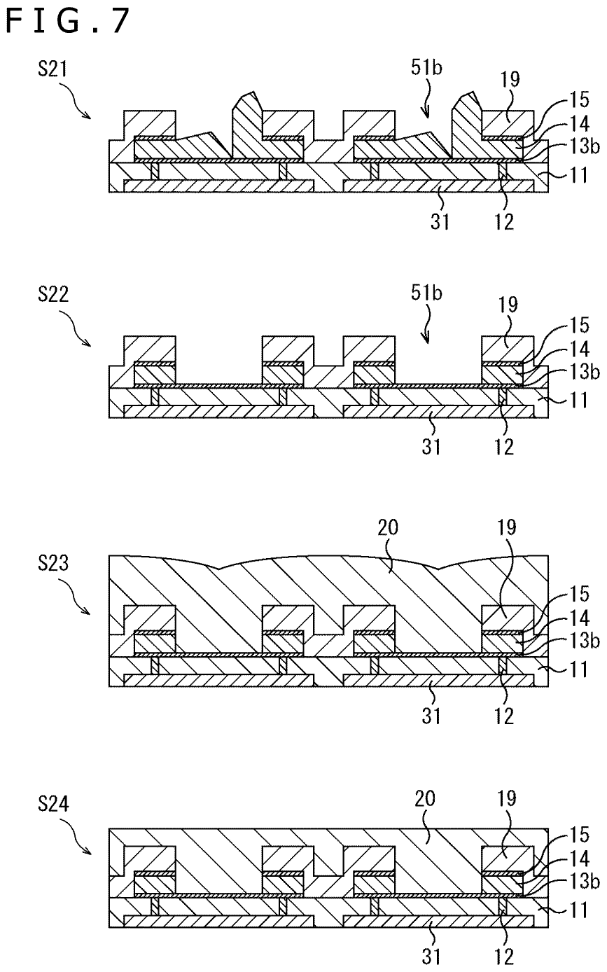

FIG. 7 depicts views illustrating a manufacturing process of the semiconductor apparatus 10b according to the second embodiment. Step S21 illustrates the pad portion 51b of the semiconductor apparatus 10b obtained after the needle 61 for inspection is pushed and the inspection is performed, and corresponds to the semiconductor apparatus 10b in the state illustrated in B of FIG. 3. The first insulating film 19 is in a state in which a part other than a necessary part thereof has been removed after its formation.

In step S22, the aluminum film 14 in a region of the pad portion 51b is removed by etching. In step S22, the aluminum film 14 is subjected to etching in such a manner that the barrier metal 13b remains, so that the barrier metal 13b remains.

In step S23, the second insulating film 20 is formed. In step S24, the second insulating film 20 is planarized by CMP, for example. Since steps S21, S23, and S24 are basically similar to steps S11, S13, and S14 illustrated in FIG. 4, detailed description thereof is omitted.

As described above, irregularities on the aluminum film 14, such as the mark 71 of the needle 61 and the protrusion 72 generated by pushing of the needle 61, are removed by etching and planarized, and the second insulating film 20 is then formed, thereby making it possible to prevent a space from being generated in the second insulating film 20 and prevent occurrence of peeling-off when another semiconductor apparatus is stacked thereon.

By the manufacturing process described above, the semiconductor apparatus 10b illustrated in FIG. 6 is manufactured. FIG. 6 is referred to again. The aluminum film 14 in the pad portion 51 is in a form of a single continuous film before the etching is performed. However, after the etching, the aluminum film 14 is in a state of being divided into one part formed in the pad electrode 17b-1 and another part formed in the pad electrode 17b-2. A surface on the upper side and a surface on the left side of the pad electrode 17b-1 in FIG. 6 are covered with the first insulating film 19, but a surface on the right side of the pad electrode 17b-1 in FIG. 6 is covered not with the first insulating film 19 but with the second insulating film 20. Similarly, a surface on the upper side and a surface on the right side of the pad electrode 17b-2 in FIG. 6 are covered with the first insulating film 19, but a surface on the left side of the pad electrode 17b-2 in FIG. 6 is covered not with the first insulating film 19 but with the second insulating film 20.

One surface of an upper surface, a left surface, a right surface, a front surface, and a rear surface of the pad electrode 17b is covered with an insulating film of a material different from that of the other four surfaces. Meanwhile, an upper surface, a left surface, a right surface, a front surface, and a rear surface of the wiring electrode 18 are all covered with an insulating film of the same material. In such a manner, the pad electrode 17b is covered with insulating films of different materials, but the wiring electrode 18 is covered with an insulating film of the same material. While the side surfaces of the pad electrode 17b are covered with different insulating films, the side surfaces of the wiring electrode 18 are covered with the same insulating film.

At least one electrode of the electrodes formed in the semiconductor apparatus 10b is configured to be covered with two or more different insulating films.

### Configuration of Semiconductor Apparatus According to Third Embodiment

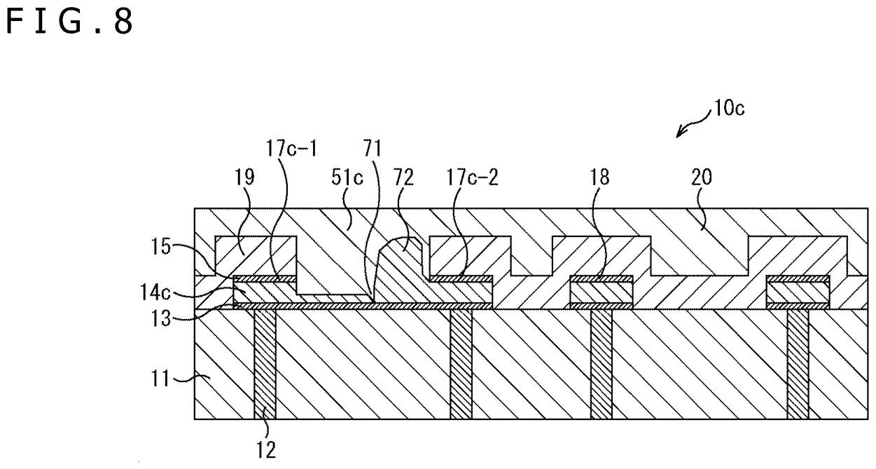

FIG. 8 is a view illustrating a configuration example of a semiconductor apparatus 10c according to the third embodiment. While only a region of the semiconductor apparatus 10c in which a pad electrode 17c and the wiring electrode 18 are located is illustrated in FIG. 8, a basic configuration of the semiconductor apparatus 10c is similar to that of the semiconductor apparatus 10a illustrated in FIG. 1 and FIG. 5.

The semiconductor apparatus 10c according to the third embodiment illustrated in FIG. 8 is different from the semiconductor apparatus 10a according to the first embodiment illustrated in FIG. 5 in that an aluminum film 14c remains in an opening of a pad portion 51c, but is similar to the semiconductor apparatus 10a in other respects.

The aluminum film 14c is provided in the pad portion 51c of the semiconductor apparatus 10c, and the second insulating film 20 is formed in a state in which the mark 71 and the protrusion 72 are present due to the needle 61 that has been used in the inspection. The highest position (referred to as an apex) of the protrusion 72 of the aluminum film 14c is located at a position lower than a surface (referred to as an interface) at which the first insulating film 19 and the second insulating film 20 formed on the pad portion 51c are in contact with each other.

The protrusion 72 is removed by etching in such a manner that the apex of the protrusion 72 of the aluminum film 14c is located at a position lower than the interface between the first insulating film 19 and the second insulating film 20. The film thickness of the first insulating film 19 may be made thick in such a manner that the interface between the first insulating film 19 and the second insulating film 20 is located at a higher position and that the apex of the protrusion 72 is located lower than the interface between the first insulating film 19 and the second insulating film 20.

### Manufacturing Process According to Third Embodiment

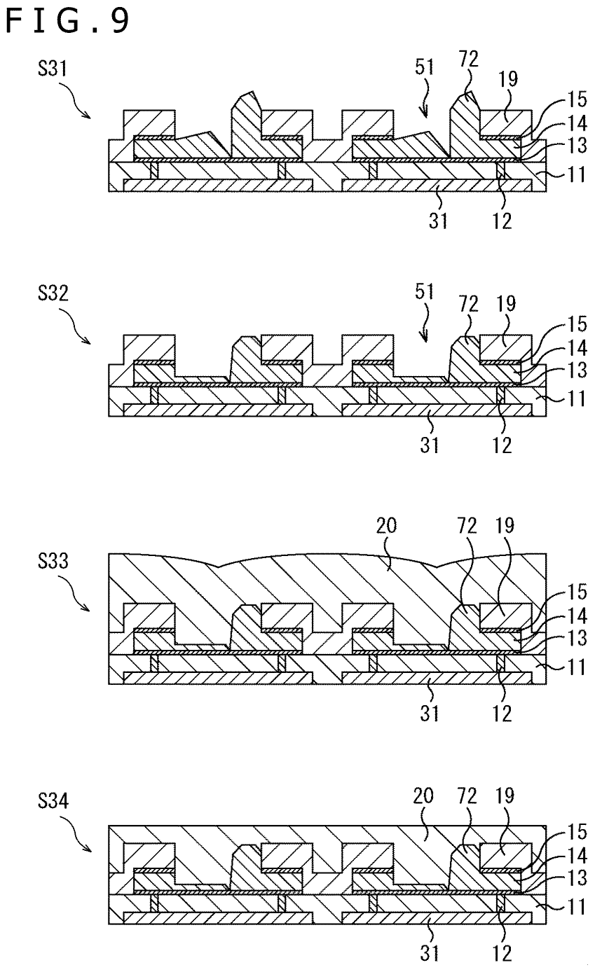

FIG. 9 depicts views illustrating a manufacturing process of the semiconductor apparatus 10c according to the third embodiment. Step S31 illustrates the semiconductor apparatus 10c obtained after the needle 61 for inspection is pushed and the inspection is performed, and corresponds to a state in which the protrusion 72 is present in the pad portion 51c.

In step S32, part of the aluminum film 14c in a region of the pad portion 51c is removed by etching. In step S32, the protrusion 72 of the aluminum film 14c is etched until the apex of the protrusion 72 of the aluminum film 14c is located at a position lower than the interface between the first insulating film 19 and the second insulating film 20.

In step S33, the second insulating film 20 is formed. In step S34, the second insulating film 20 is planarized by CMP, for example. Since steps S31, S33, and S34 are basically similar to steps S11, S13, and S14 illustrated in FIG. 4, detailed description thereof is omitted.

As described above, part of the protrusion 72 generated by pushing of the needle is removed, and the second insulating film 20 is thereafter formed, thereby making it possible to prevent a space from being generated in the second insulating film 20 and prevent occurrence of peeling-off when another semiconductor apparatus is stacked thereon.

By the manufacturing process described above, the semiconductor apparatus 10c illustrated in FIG. 8 is manufactured. FIG. 8 is referred to again. Even if the apex of the protrusion 72 of the aluminum film 14c in the pad portion 51 is located at a position higher than the interface between the first insulating film 19 and the second insulating film 20 before etching is performed, the apex of the protrusion 72 is in a state of being located at a position lower than the interface between the first insulating film 19 and the second insulating film 20 after etching is performed.

A surface on the upper side and a surface on the left side of a pad electrode 17c-1 in FIG. 8 are covered with the first insulating film 19, but a surface on the right side of the pad electrode 17c-1 in FIG. 8 is covered not with the first insulating film 19 but with the second insulating film 20. Similarly, a surface on the upper side and a surface on the right side of a pad electrode 17c-2 in FIG. 8 are covered with the first insulating film 19, but a surface on the left side of the pad electrode 17c-2 in FIG. 8 is covered not with the first insulating film 19 but with the second insulating film 20.

The upper surface and one side surface of the side surfaces of the pad electrode 17c are covered with an insulating film of a material different from that of the other side surfaces. Meanwhile, the upper surface and the side surfaces of the wiring electrode 18 are all covered with an insulating film of the same material. In such a manner, the pad electrode 17c is covered with insulating films of different materials, but the wiring electrode 18 is covered with an insulating film of the same material. While the side surfaces of the pad electrode 17c are covered with different insulating films, the side surfaces of the wiring electrode 18 are covered with the same insulating film.

At least one electrode of the electrodes formed in the semiconductor apparatus 10c is configured to be covered with two or more different insulating films.

### Configuration of Semiconductor Apparatus According to Fourth Embodiment

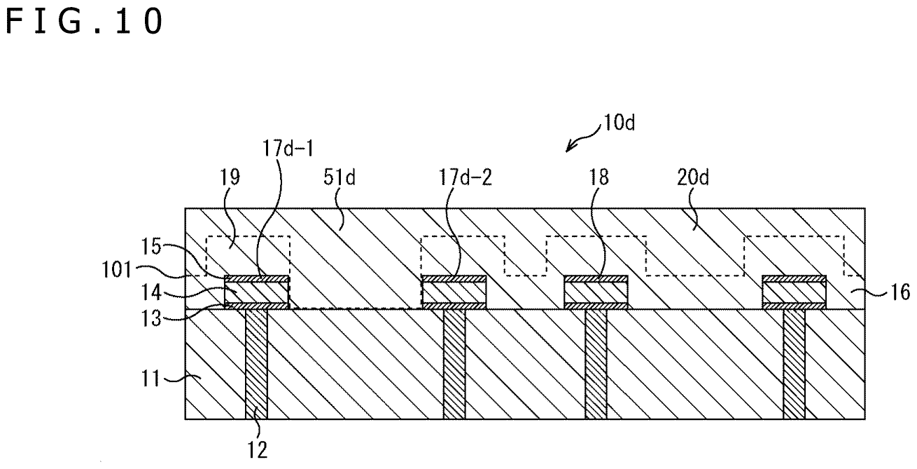

FIG. 10 is a view illustrating a configuration example of a semiconductor apparatus 10d according to the fourth embodiment. While only a region of the semiconductor apparatus 10d in which a pad electrode 17d and the wiring electrode 18 are located is illustrated in FIG. 10, a basic configuration of the semiconductor apparatus 10d is similar to that of the semiconductor apparatus 10a illustrated in FIG. 1 and FIG. 5.

The semiconductor apparatus 10d according to the fourth embodiment illustrated in FIG. 10 is different from the semiconductor apparatus 10a according to the first embodiment illustrated in FIG. 5 in that the first insulating film 19 and the second insulating film 20 are formed by the same material and that a liner film 101 is formed between the first insulating film 19 and the second insulating film 20, but is similar to the semiconductor apparatus 10a in other respects.

In an opening of a pad portion 51d of the semiconductor apparatus 10d, the liner film 101 is formed on the semiconductor substrate 11, and a second insulating film 20d of the same material as that of the first insulating film 19 is formed on the liner film 101.

Note that, as with the second embodiment, a configuration in which the barrier metal 13 remains, the liner film 101 is formed on the barrier metal 13, and the second insulating film 20d is formed on the liner film 101 can also be adopted. Further, as with the third embodiment, a configuration in which the barrier metal 13 and the aluminum film 14 remain, the liner film 101 is formed on the aluminum film 14, and the second insulating film 20d is formed on the liner film 101 can also be adopted.

### Manufacturing Process According to Fourth Embodiment

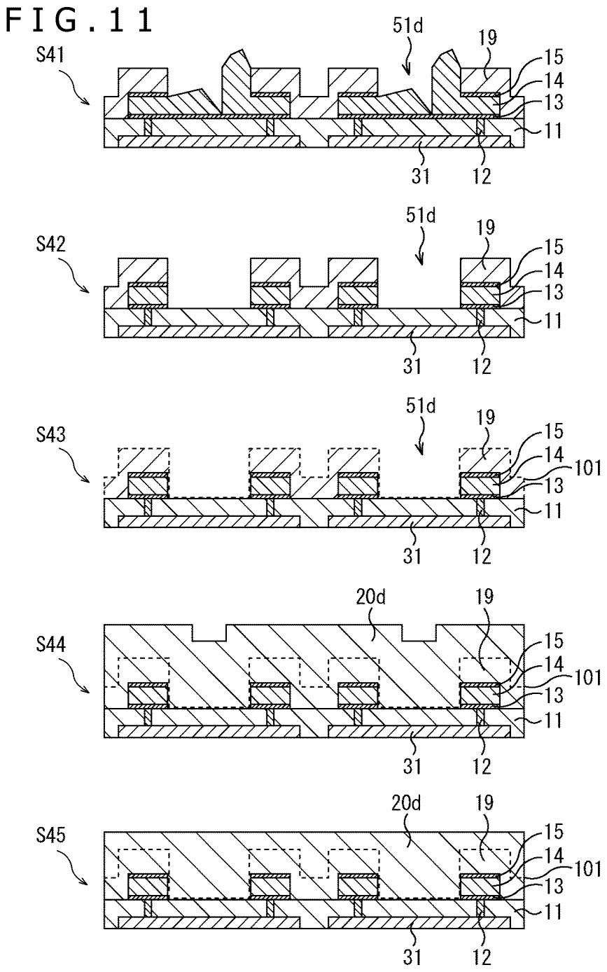

FIG. 11 depicts views illustrating a manufacturing process of the semiconductor apparatus 10d according to the fourth embodiment. Step S41 illustrates the semiconductor apparatus 10d obtained after the needle 61 for inspection is pushed and the inspection is performed, the semiconductor apparatus 10d being in a state in which the aluminum film 14 includes the protrusion 72 as a part thereof.

In step S42, the aluminum film 14 and the barrier metal 13 in a region corresponding to the opening of the pad portion 51 are removed by etching. In step S42, the second embodiment may be applied to step S42, and with use of the same treatment as that of step S22, only the aluminum film 14 may be removed by etching. In step S42, the third embodiment may be applied to step S42, and with use of the same treatment as that of step S32, only part of the protrusion 72 of the aluminum film 14 may be removed by etching.

In step S43, the liner film 101 is formed on the first insulating film 19 and the semiconductor substrate 11 exposed in the opening of the pad portion 51d.

In step S44, the second insulating film 20d is formed. In step S45, the second insulating film 20d is planarized by CMP, for example. Since steps S41, S42, S44, and S45 are basically similar to steps S11, S12, S13, and S14 illustrated in FIG. 4, detailed description thereof is omitted.

As described above, irregularities on the aluminum film 14, such as the mark 71 of the needle 61 and the protrusion 72 generated by pushing of the needle 61, are removed by etching and planarized, and the liner film 101 and the second insulating film 20d are then formed, thereby making it possible to prevent a space from being generated in the second insulating film 20 and prevent occurrence of peeling-off when another semiconductor apparatus is stacked thereon.

By the manufacturing process described above, the semiconductor apparatus 10d illustrated in FIG. 10 is manufactured. FIG. 10 is referred to again. The aluminum film 14 in the pad portion 51 is in a form of a single continuous film before the etching is performed. However, after the etching, the aluminum film 14 is in a state of being divided into one part formed in a pad electrode 17d-1 and another part formed in a pad electrode 17d-2. A surface on the upper side and a surface on the left side of the pad electrode 17d-1 in FIG. 10 are covered with the first insulating film 19, but a surface on the right side of the pad electrode 17d-1 in FIG. 10 is covered not with the first insulating film 19 but with the liner film 101. Similarly, a surface on the upper side and a surface on the right side of the pad electrode 17d-2 in FIG. 10 are covered with the first insulating film 19, but a surface on the left side of the pad electrode 17d-2 in FIG. 10 is covered not with the first insulating film 19 but with the second insulating film 20.

The upper surface and one side surface of the side surfaces of the pad electrode 17d are covered with an insulating film of a material different from that of the other side surfaces. Meanwhile, the upper surface and the side surfaces of the wiring electrode 18 are all covered with an insulating film of the same material. In such a manner, the pad electrode 17d is covered with insulating films of different materials, but the wiring electrode 18 is covered with an insulating film of the same material. While the side surfaces of the pad electrode 17d are covered with different insulating films, the side surfaces of the wiring electrode 18 are covered with the same insulating film.

At least one electrode of the electrodes formed in the semiconductor apparatus 10d is configured to be covered with two or more different insulating films.

### Configuration of Semiconductor Apparatus According to Fifth Embodiment

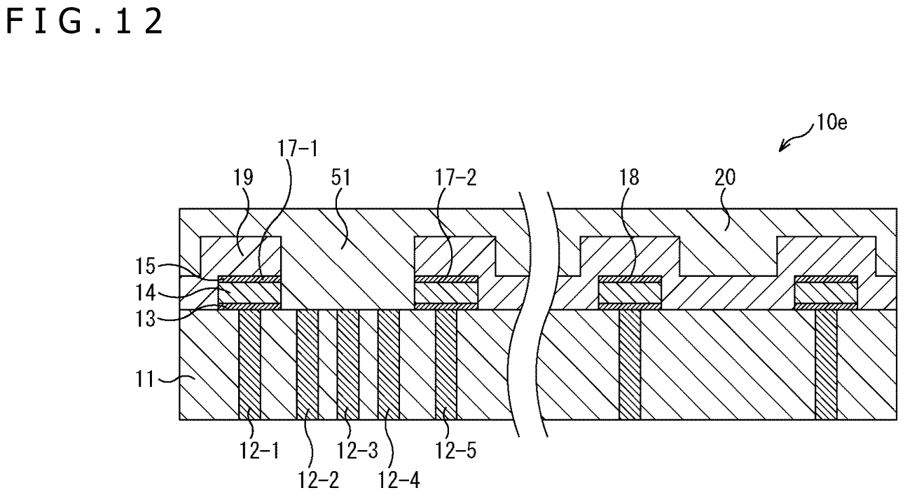

FIG. 12 is a view illustrating a configuration example of a semiconductor apparatus 10e according to the fifth embodiment. The fifth embodiment can be implemented in combination with any of the first to fourth embodiments. FIG. 12 is a view illustrating a configuration of the semiconductor apparatus 10e obtained in a case where the fifth embodiment is combined with the first embodiment.

In the first to fourth embodiments described above, a case where the electrode 12 is not formed in a region located in the opening of the pad portion 51 in the semiconductor substrate 11 is illustrated and described. As illustrated in FIG. 12, the electrodes 12 may be formed in a region of the semiconductor substrate 11 located in the opening of the pad portion 51. In the example illustrated in FIG. 12, electrodes 12-2 to 12-4 are formed in the region of the semiconductor substrate 11 located in the opening of the pad portion 51.

An electrode 12-1 is connected to the pad electrode 17-1, and an electrode 12-5 is connected to the pad electrode 17-2. Before etching is performed, that is, when an inspection is performed, the aluminum film 14 is present also in the opening of the pad portion 51 (this aluminum film 14 is not illustrated in FIG. 12), and this aluminum film 14 is connected to the electrodes 12-2 to 12-4. After the etching is performed, since the aluminum film 14 in the opening of the pad portion 51 has been removed, the electrodes 12-2 to 12-4 remain, and the second insulating film 20 is formed on the electrodes 12-2 to 12-4, as illustrated in FIG. 12.

As described above, a configuration in which the electrodes 12 are formed in the region of the semiconductor substrate 11 located in the opening of the pad portion 51 can also be adopted. The electrodes 12 in the opening of the pad portion 51 are exposed when etching is performed, but the electrodes 12 are covered with the second insulating film 20 after the etching, resulting in an insulated structure.

The present technology can be applied regardless of the layout of the electrodes of the pad portion 51, and the aluminum film 14 is removed, so that such a configuration described above can be achieved.

### Configuration of Semiconductor Apparatus According to Sixth Embodiment

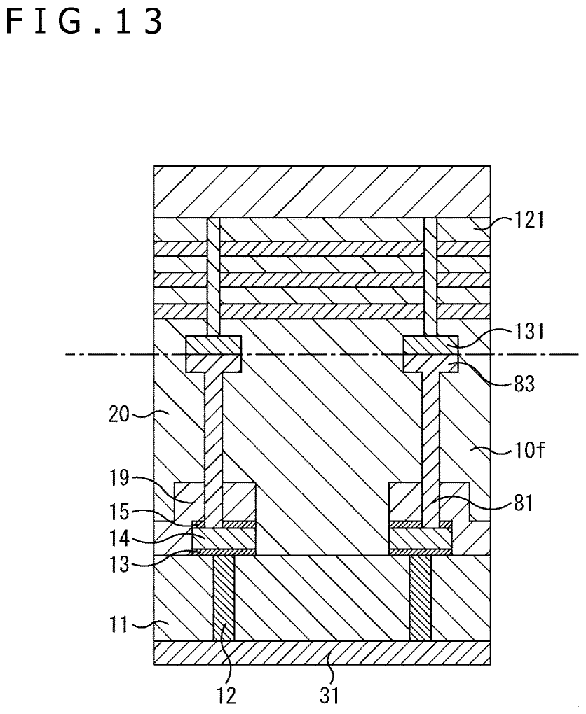

FIG. 13 is a view illustrating a configuration example of a semiconductor apparatus 10f according to the sixth embodiment. The sixth embodiment can be implemented in combination with any of the first to fifth embodiments. FIG. 13 is a view illustrating a configuration of the semiconductor apparatus 10f obtained in a case where the sixth embodiment is combined with the first embodiment.

The semiconductor apparatus 10f illustrated in FIG. 13 has a configuration in which the pad electrodes 17 left after etching is performed are connected to a wire for establishing electrical connection to another stacked semiconductor apparatus (a semiconductor apparatus 121 in FIG. 13). The pad electrode 17 has one end thereof connected to the electrode 12 (referred to as a lower electrode 12) provided in the semiconductor substrate 11, and the other end thereof connected to an electrode 81 (referred to as an upper electrode 81).

Since the pad electrode 17 is configured to be connected to the upper electrode 81, the first insulating film 19 and the second insulating film 20 in a region where the upper electrode 81 is disposed have been removed. The upper electrode 81 is connected to an electrode 83 provided on a connection interface between the semiconductor apparatus 10f and the semiconductor apparatus 121. The electrode 83 is connected to an electrode 113 of the semiconductor apparatus 121. Since the electrode 83 and an electrode 131 are connected to each other, the semiconductor apparatus 10f and the semiconductor apparatus 121 are electrically connected to each other and have the same potential.

In such a manner, the pad electrode 17 can be configured to function as a pad on which a needle for inspection is pushed when an inspection is performed in the manufacturing and to be used as an electrode for establishing electrical connection to another semiconductor apparatus after etching is performed after the inspection.

In the semiconductor apparatus 10f, a needle is pushed onto the aluminum film 14 in the pad portion 51 to perform measurement, allowing for selection of a non-defective product, the second insulating film 20 is planarized, and the upper electrode 81 is formed on the pad electrode 17, thereby making it possible to form a surface of the upper electrode 81 on a flat surface. The semiconductor apparatus 121 stacked on the semiconductor apparatus 10f also has an electrode that is planarized and that is connected to the semiconductor apparatus 10f, so that a stacked structure in which the semiconductor apparatus 121 and the semiconductor apparatus 10f are electrically connected to each other can be formed.

### Configuration of Semiconductor Apparatus According to Seventh Embodiment

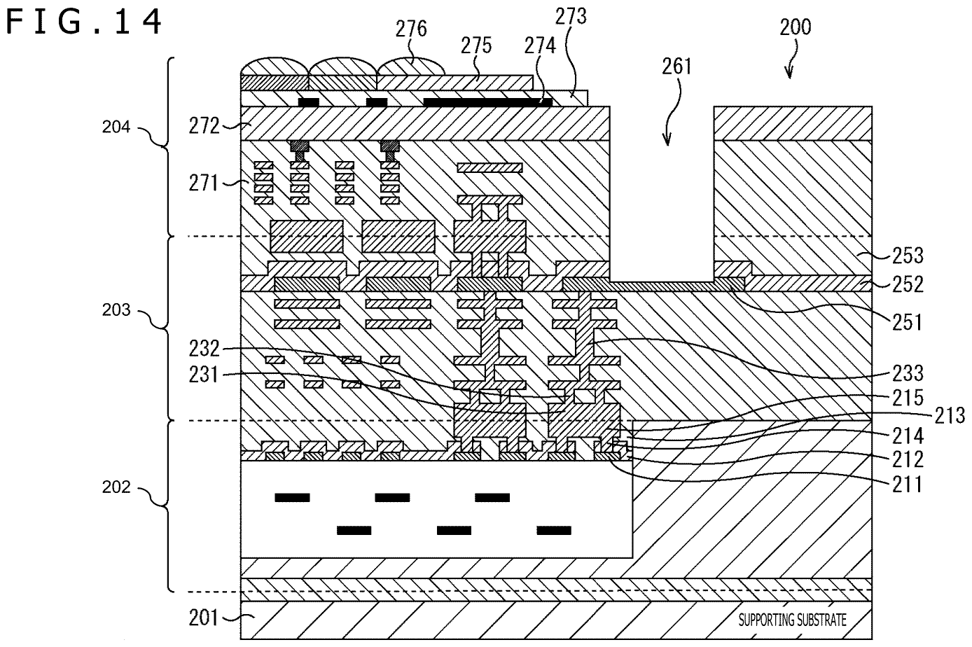

FIG. 14 is a view illustrating a configuration example of a semiconductor apparatus 10 according to the seventh embodiment. The semiconductor apparatus 10 according to the seventh embodiment illustrated in FIG. 14 illustrates a case where the first to sixth embodiments are applied to an imaging apparatus.

In an imaging apparatus 200 illustrated in FIG. 14, a chip 202, a chip 203, and a chip 204 are stacked in this order on a supporting substrate 201. The chip 204 is a chip in which an imaging element is disposed. The chip 203 can be a memory that stores a signal from the imaging element, a logic circuit that processes a signal from the imaging element, or the like, for example. The chip 204 can also be a memory that stores a signal from the imaging element, a logic circuit that processes a signal from the imaging element, or the like, for example.

Since the chip 202 is small as compared to the chip 203, an embedded film 205 is formed on the right side of the chip 202 in FIG. 14 in order to absorb the difference in size between the chip 202 and the chip 203. In a case where the chip 202 and the chip 203 are formed in a substantially same size, a configuration in which the embedded film 205 is not provided can also be adopted.

The chip 202 has a configuration of the semiconductor apparatus 10 described above. An electrode 211 of the chip 202 corresponds to the pad electrode 17. An upper electrode 214 is connected to the electrode 211. The upper electrode 214 is connected to a connecting electrode 216 provided on an interface between the chip 202 and the chip 203.

The upper electrode 214 is disposed in a region where a first insulating film 212 (which corresponds to the first insulating film 19 in the embodiments described above) and a second insulating film 213 (which corresponds to the second insulating film 20 in the embodiments described above) have been removed. The configuration of the semiconductor apparatus 10f illustrated in FIG. 13 is applied to the chip 202.

In the chip 203, a connecting electrode 231 connected to a connecting electrode 215 is formed on the interface between the chip 202 and the chip 203. An electrode 232 is connected to the connecting electrode 231. An electrode 233 is connected to the electrode 232. The electrode 233 is connected to an electrode pad 251. The electrode pad 251 is used as a terminal for external connection.

For example, in a case where a power supply having a predetermined voltage is connected to the electrode pad 251 used as a terminal for external connection, the chip 202 and the chip 203 can have a configuration in which power is supplied from the external power supply thus connected.

A first insulating film 252 is stacked on both ends of the electrode pad 251, and a second insulating film 253 is stacked on the first insulating film 252. The electrode pad 251 for external connection may be formed at, but is not limited to, the position illustrated in FIG. 14, and the electrode pad 251 may be formed at a deeper position in the chip 203 than that illustrated in FIG. 14. The electrode pad 251 for external connection may be formed in the chip 204.

The chip 204 is a sensor chip, and an imaging element layer 272 in which a photodiode is disposed is formed on a wiring layer 271. A planarized film 273 is formed on the imaging element layer 272, and a light shielding film 224 is formed in the planarized film 273. A color filter layer 275 is provided on the planarized film 273. An on-chip lens 276 is formed for each pixel on the color filter layer 275.

Any one or some of the chips 202 to 204 included in the imaging apparatus 200 described above can be a chip (chips) having the configuration of the semiconductor apparatus 10 according to the embodiments described above. The number of chips to be stacked is not limited to three, and chips can be stacked in any number according to the application range of the present technology. As described above, according to the present technology, in a case where multiple chips (semiconductor apparatuses) are stacked on each other, it is possible to prevent the connection strength between the stacked chips from being reduced.

Although a case where the present technology is applied to the imaging apparatus 200 has been described as an example here, the present technology can also be applied to another apparatus including a semiconductor apparatus.

### Example of Application to Electronic Equipment

The present technology is applicable to electronic equipment in general that uses an imaging element for an image capturing unit (photoelectric conversion unit), such as an imaging apparatus as exemplified by a digital still camera, a video camera, or the like, a portable terminal apparatus having an imaging function, and a copying machine that uses an imaging element for an image reading unit. The imaging element may have a one-chip form, or may have a module-shaped form having an imaging function as a package in which an imaging unit and a signal processing unit or an optical system are all disposed.

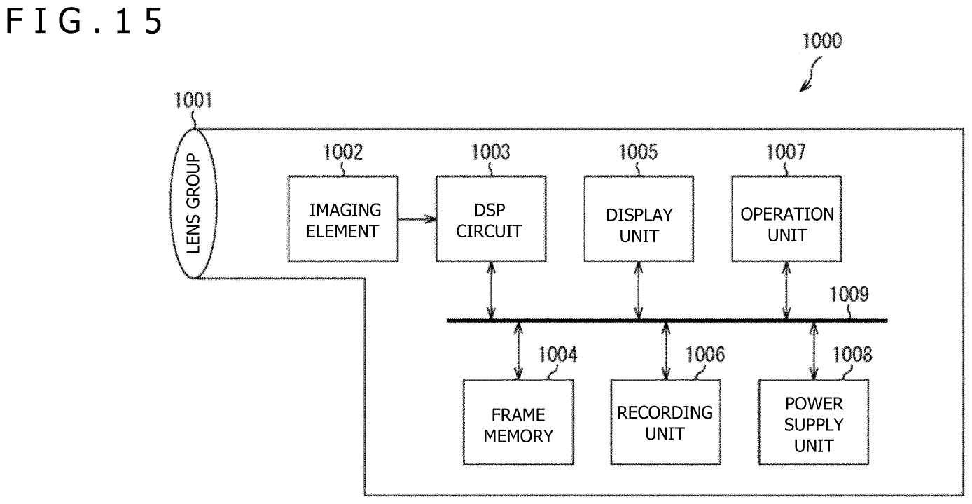

FIG. 15 is a block diagram illustrating a configuration example of an imaging apparatus as electronic equipment to which the present technology is applied.

An imaging apparatus 1000 illustrated in FIG. 15 includes an optical unit 1001 having a lens group and the like, an imaging element (image capturing device) 1002, and a DSP (Digital Signal Processor) circuit 1003 which is a camera signal processing circuit. Further, the imaging apparatus 1000 also includes a frame memory 1004, a display unit 1005, a recording unit 1006, an operation unit 1007, and a power supply unit 1008. The DSP circuit 1003, the frame memory 1004, the display unit 1005, the recording unit 1006, the operation unit 1007, and the power supply unit 1008 are connected to one another via a bus line 1009.

The optical unit 1001 takes in incident light (image light) coming from a subject, and forms an image of the incident light on an imaging surface of the imaging element 1002. After the image of the incident light is formed on the imaging surface by the optical unit 1001, the imaging element 1002 converts the light amount of the incident light into electric signals for each pixel, and outputs the electric signals as pixel signals.

For example, the display unit 1005 includes a thin display such as an LCD (Liquid Crystal Display) and an organic EL (Electro Luminescence) display, and displays moving images or still images captured by the imaging element 1002. The recording unit 1006 records the moving images or the still images captured by the imaging element 1002 in a recording medium such as a hard disk and a semiconductor memory.

The operation unit 1007 issues operation commands associated with various functions of the imaging apparatus 1000, under operation performed by a user. The power supply unit 1008 appropriately supplies various types of power supplies corresponding to operation power supplies for the DSP circuit 1003, the frame memory 1004, the display unit 1005, the recording unit 1006, and the operation unit 1007 to these supply targets.

The imaging apparatus 200 illustrated in FIG. 14 can be applied to the imaging element 1002 illustrated in FIG. 15.

In the present specification, a system is referred to as an apparatus as a whole including multiple apparatuses.

Note that effects described in the present specification are merely examples and are not limitative and that other effects may be produced.

Note that embodiments of the present technology are not limited to the embodiments described above and can be modified in various manners within the scope not departing from the gist of the present technology.

Note that the present technology can also be configured as follows.

(1)

A semiconductor apparatus including:
a first electrode covered with a first insulating film; and
a second electrode covered with the first insulating film and a second insulating film of a material different from that of the first insulating film.
   (2)

The semiconductor apparatus according to (1) above, in which
at least one surface of side surfaces of the second electrode is covered with the second insulating film, and a remaining surface thereof is covered with the first insulating film.
   (3)

The semiconductor apparatus according to (1) or (2) above, in which
the second insulating film is formed on the first insulating film.
   (4)

The semiconductor apparatus according to any one of (1) to (3) above, in which
the second electrode includes a third electrode and a fourth electrode, and
the second insulating film is formed between the third electrode and the fourth electrode.
   (5)

The semiconductor apparatus according to (4) above, in which
a barrier metal included in the third electrode and a barrier metal included in the fourth electrode are connected to each other, and
the second insulating film is formed on the barrier metal located between the third electrode and the fourth electrode.
   (6)

The semiconductor apparatus according to (4) above, in which
a conductor included in the third electrode and a conductor included in the fourth electrode are connected to each other, and
the second insulating film is formed on the conductor located between the third electrode and the fourth electrode.
   (7)

The semiconductor apparatus according to any one of (1) to (3) above, in which
the first insulating film and the second insulating film are formed by a same material, and
a liner film is formed between the first insulating film and the second insulating film.
   (8)

The semiconductor apparatus according to (7) above, in which
at least one surface of side surfaces of the second electrode is covered with the liner film.
   (9)

The semiconductor apparatus according to any one of (1) to (8) above, in which
the second electrode forms part of a pad onto which a needle for inspection is pushed when it is determined whether the semiconductor apparatus is non-defective.
   (10)

The semiconductor apparatus according to any one of (1) to (9) above, in which
the second electrode is electrically connected to another stacked semiconductor apparatus.
   (11)

The semiconductor apparatus according to any one of (1) to (10) above, in which
the second electrode is connected to a terminal for external connection.
   (12)

The semiconductor apparatus according to any one of (1) to (11) above, in which

the semiconductor apparatus is stacked on a semiconductor apparatus including an imaging element.

(13)

A method for manufacturing a semiconductor apparatus, the method including:
removing a conductive material located in an opening of a pad onto which a needle for inspection has been pushed when an inspection to determine whether the semiconductor apparatus is non-defective has been performed;
forming a second insulating film of a material different from that of a first insulating film formed on the conductive material of the pad, on a region including a region from which the conductive material has been removed; and
planarizing the second insulating film thus formed.

### REFERENCE SIGNS LIST

10: Semiconductor apparatus
11: Semiconductor substrate
12: Electrode
13: Barrier metal
14: Aluminum film
15: Titanium film
17: Pad electrode
18: Wiring electrode
19: First insulating film
20: Second insulating film
31: Wire
51: Pad portion
61: Needle
71: Mark
72: Protrusion
81: Electrode
83: Electrode
101: Liner film
113: Electrode
121: Semiconductor apparatus
131: Electrode
200: Imaging apparatus
201: Supporting substrate
202: Chip
203: Chip
204: Chip
205: Embedded film
211: Electrode
212: First insulating film
213: Second insulating film
214: Upper electrode
215: Connecting electrode
216: Connecting electrode
224: Light shielding film
231: Connecting electrode
232: Electrode
233: Electrode
251: Electrode pad
252: First insulating film
253: Second insulating film
271: Wiring layer
272: Imaging element layer
273: Planarized film
275: Color filter layer
276: On-chip lens

What is claimed is:

1. A semiconductor apparatus comprising:
a first electrode covered with a first insulating film; and
a second electrode covered with the first insulating film and a second insulating film of a material different from that of the first insulating film.

2. The semiconductor apparatus according to claim 1, wherein
at least one surface of side surfaces of the second electrode is covered with the second insulating film, and a remaining surface thereof is covered with the first insulating film.

3. The semiconductor apparatus according to claim 1, wherein
the second insulating film is formed on the first insulating film.

4. The semiconductor apparatus according to claim 1, wherein
the second electrode includes a third electrode and a fourth electrode, and
the second insulating film is formed between the third electrode and the fourth electrode.

5. The semiconductor apparatus according to claim 4, wherein
a barrier metal included in the third electrode and a barrier metal included in the fourth electrode are connected to each other, and
the second insulating film is formed on the barrier metal located between the third electrode and the fourth electrode.

6. The semiconductor apparatus according to claim 4, wherein
a conductor included in the third electrode and a conductor included in the fourth electrode are connected to each other, and
the second insulating film is formed on the conductor located between the third electrode and the fourth electrode.

7. The semiconductor apparatus according to claim 1, wherein
the first insulating film and the second insulating film are formed by a same material, and
a liner film is formed between the first insulating film and the second insulating film.

8. The semiconductor apparatus according to claim 7, wherein
at least one surface of side surfaces of the second electrode is covered with the liner film.

9. The semiconductor apparatus according to claim 1, wherein
the second electrode forms part of a pad onto which a needle for inspection is pushed when it is determined whether the semiconductor apparatus is non-defective.

10. The semiconductor apparatus according to claim 1, wherein
the second electrode is electrically connected to another stacked semiconductor apparatus.

11. The semiconductor apparatus according to claim 1, wherein
the second electrode is connected to a terminal for external connection.

12. The semiconductor apparatus according to claim 1, wherein
the semiconductor apparatus is stacked on a semiconductor apparatus including an imaging element.

13. A method for manufacturing a semiconductor apparatus, the method comprising:
removing a conductive material located in an opening of a pad onto which a needle for inspection has been pushed when an inspection to determine whether the semiconductor apparatus is non-defective has been performed;
forming a second insulating film of a material different from that of a first insulating film formed on the conductive material of the pad, on a region including a region from which the conductive material has been removed; and
planarizing the second insulating film thus formed.
